(19) United States
(12) Patent Application Publication
(10) Pub. No.: US 2024/0410841 A1
(43) Pub. Date: Dec. 12, 2024

(54) DEFECT DEPTH ESTIMATION FOR A SEMICONDUCTOR SPECIMEN

(71) Applicant: Applied Materials Israel Ltd., Rehovot (IL)

(72) Inventor: Vadim KUCHIK, Kiriat Ekron (IL)

(21) Appl. No.: 18/673,251

(22) Filed: May 23, 2024

(30) Foreign Application Priority Data
Jun. 6, 2023 (IL) 303495

(51) Int. Cl. G01N 23/203

(52) U.S. Cl. CPC G01N 23/203; G01N 2223/053; G01N 2223/102; G01N 2223/304; G01N 2223/305; G01N 2223/3303; G01N 2223/418; G01N 2223/646

(57) ABSTRACT

There is provided a system and method of examining a defect buried in a semiconductor specimen. The method comprises: scanning the semiconductor specimen using an electron beam with a given landing energy (LE); generating image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; obtaining a measurement related to the defect based on the image data; and estimating an actual depth of the defect in the specimen based on the measurement and the relationship.

### RELATED APPLICATIONS

This application claims the benefit of priority from Israeli Patent Application No. 303495, filed Jun. 6, 2023, which is incorporated herein by reference.

### TECHNICAL FIELD

The presently disclosed subject matter relates, in general, to the field of examination of a semiconductor specimen, and more specifically, to examination of a defect buried in a semiconductor specimen.

### BACKGROUND

Current demands for high density and performance associated with ultra large-scale integration of fabricated devices require submicron features, increased transistor and circuit speeds, and improved reliability. As semiconductor processes progress, pattern dimensions such as line width, and other types of critical dimensions, are continuously shrunken. Such demands require formation of device features with high precision and uniformity, which, in turn, necessitates careful monitoring of the fabrication process, including automated examination of the devices while they are still in the form of semiconductor wafers.

Examination can be provided by using non-destructive examination tools during or after manufacture of the specimen to be examined. Examination generally involves generating certain output (e.g., images, signals, etc.) for a specimen by directing light or electrons to the wafer and detecting the light or electrons from the wafer. A variety of non-destructive examination tools includes, by way of non-limiting example, scanning electron microscopes, atomic force microscopes, optical inspection tools, etc.

Examination processes can include a plurality of examination steps. The manufacturing process of a semiconductor device can include various procedures such as etching, depositing, planarization, growth such as epitaxial growth, implantation, etc. The examination steps can be performed a multiplicity of times, for example after certain process procedures, and/or after the manufacturing of certain layers, or the like. Additionally, or alternatively, each examination step can be repeated multiple times, for example for different wafer locations, or for the same wafer locations with different examination settings.

Examination processes are used at various steps during semiconductor fabrication for purpose of process control, such as, e.g., defect detection and classification processes, as well as metrology related operations. Effectiveness of examination can be improved by automatization of process(es) such as, for example, defect detection, Automatic Defect Classification (ADC), Automatic Defect Review (ADR), image segmentation, automated metrology-related operations, etc.

Automated examination systems ensure that the parts manufactured meet the quality standards expected and provide useful information on adjustments that may be needed to the manufacturing tools, equipment, and/or compositions, depending on the type of defects/measurements identified.

### SUMMARY

In accordance with certain aspects of the presently disclosed subject matter, there is provided a computerized system for examining a defect buried in a semiconductor specimen, the system comprising: an examination tool configured to scan the semiconductor specimen using an electron beam with a given landing energy (LE), and generate image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and a processing circuitry operatively connected to the examination tool, and configured to obtain a measurement related to the defect based on the image data, and estimate an actual depth of the defect in the specimen based on the measurement and the relationship.

In addition to the above features, the system according to this aspect of the presently disclosed subject matter can comprise one or more of features (i) to (ix) listed below, in any desired combination or permutation which is technically possible:
(i). The specific EE can be selected from the series of EEs as an EE that provides a relatively large separation between the expected measurements for the different expected depths of the defect.
(ii). The relationship can be derived by performing simulation of the expected measurements at the series of EEs, based on material and structural properties of the semiconductor specimen.
(iii). The relationship can be derived by configuring the examination tool with multiple detectors each configured for collecting BSEs at a respective EE of the series of EEs, scanning a set of test specimens having the defect located at different depths by the examination tool using the given LE, and obtaining the expected measurements at the series of EEs, based on the BSEs respectively collected by the multiple detectors.
(iv). The examination tool can be configured with a band pass filter operatively connected to a BSE detector, wherein the band pass filter is configured to filter out BSEs emitted with one or more EEs other than the specific EE, thereby enabling the BSE detector to collect BSEs emitted only at the specific EE.
(v). The examination tool can be configured with a band pass filter operatively connected to a BSE detector, wherein the band pass filter is configured to filter out BSEs emitted with one or more EEs other than the specific EE, thereby enabling the BSE detector to collect BSEs emitted only at the specific EE.
(vi). The semiconductor specimen can comprise multiple layers and the defect can be expected to be located at a set of candidate layers of the multiple layers.
(vii). The semiconductor specimen can be a Gate-all-around (GAA) transistor, and the defect can be a residue expected to be located at a plurality of etching layers.
(viii). The semiconductor specimen can consist of a single layer and the defect is expected to be located at different depth levels in the single layer.
(ix). The estimation of the actual depth of the defect based on the measurement and the relationship has improved throughput and accuracy with respect to estimation based on measurements obtained by scanning the specimen multiple times using multiple LEs.

In accordance with other aspects of the presently disclosed subject matter, there is provided a method of examining a defect buried in a semiconductor specimen, the method comprising: scanning, by an examination tool, the semiconductor specimen using an electron beam with a given landing energy (LE), and generating image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and obtaining, by a processing circuitry operatively connected to the examination tool, a measurement related to the defect based on the image data, and estimating an actual depth of the defect in the specimen based on the measurement and the relationship.

This aspect of the disclosed subject matter can comprise one or more of features (i) to (ix) listed above with respect to the system, mutatis mutandis, in any desired combination or permutation which is technically possible.

In accordance with other aspects of the presently disclosed subject matter, there is provided a non-transitory computer readable medium comprising instructions that, when executed by a computer, cause the computer to perform a method of examining a defect buried in a semiconductor specimen, the method comprising: causing an examination tool to scan the semiconductor specimen using an electron beam with a given landing energy (LE), and generating image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and obtaining a measurement related to the defect based on the image data, and estimating an actual depth of the defect in the specimen based on the measurement and the relationship.

This aspect of the disclosed subject matter can comprise one or more of features (i) to (ix) listed above with respect to the system, mutatis mutandis, in any desired combination or permutation which is technically possible.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a generalized flowchart of estimating the depth of a defect buried in a semiconductor specimen in accordance with certain embodiments of the presently disclosed subject matter.

FIG. 3 illustrates a generalized flowchart of deriving the relationship between the expected measurements and the series of EEs for different defect depths in the specimen based on experiments in accordance with certain embodiments of the presently disclosed subject matter.

FIG. 4 illustrates a schematic graph of measurements obtained at different levels of LEs for a defect located at different depths of a specimen.

FIG. 5 shows a few examples where the LE sweep does not always provide reliable depth estimation in accordance with certain embodiments of the presently disclosed subject matter.

FIG. 6 shows an exemplary GAA structure with four possible depth levels for a residue defect and an exemplary graph demonstrating relationships between expected measurements and a series of EEs for the four different depth levels in accordance with certain embodiments of the presently disclosed subject matter.

FIG. 7 shows another graph illustrating the relationship between the measurements for different depth levels at multiple EEs in accordance with certain embodiments of the presently disclosed subject matter.

FIG. 8 shows a few graphs illustrating a set of relationships derived corresponding to a set of LEs for a GAA structure in accordance with certain embodiments of the presently disclosed subject matter.

### DETAILED DESCRIPTION OF EMBODIMENTS

In the following detailed description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits, have not been described in detail so as not to obscure the presently disclosed subject matter.

Unless specifically stated otherwise, as apparent from the following discussions, it is appreciated that throughout the specification discussions utilizing terms such as “examining”, “scanning”, “generating”, “selecting”, “obtaining”, “estimating”, “identifying”, “providing”, “collecting”, “performing”, “simulating”, “configuring”, “filtering”, “deriving”, or the like, refer to the action(s) and/or process(es) of a computer that manipulate and/or transform data into other data, said data represented as physical, such as electronic, quantities and/or said data representing the physical objects. The term “computer” should be expansively construed to cover any kind of hardware-based electronic device with data processing capabilities, such as, e.g., a personal computer, a server, a computing system, a communication device, and any other electronic computing device, including, by way of non-limiting example, the examination system, the defect depth estimation system, and respective parts thereof disclosed in the present application.

The terms “non-transitory memory” and “non-transitory storage medium” used herein should be expansively construed to cover any volatile or non-volatile computer memory suitable to the presently disclosed subject matter. The terms should be taken to include a single medium or multiple media (e.g., a centralized or distributed database, and/or associated caches and servers) that store the one or more sets of instructions. The terms shall also be taken to include any medium that is capable of storing or encoding a set of instructions for execution by the computer and that cause the computer to perform any one or more of the methodologies of the present disclosure. The terms shall accordingly be taken to include, but not be limited to, a read only memory (“ROM”), random access memory (“RAM”), magnetic disk storage media, optical storage media, flash memory devices, etc.

The term “specimen” used in this specification should be expansively construed to cover any kind of physical objects or substrates including wafers, masks, reticles, and other structures, combinations, and/or parts thereof used for manufacturing semiconductor integrated circuits, magnetic heads, flat panel displays, and other semiconductor-fabricated articles. A specimen is also referred to herein as a semiconductor specimen, and can be produced by manufacturing equipment executing corresponding manufacturing processes.

The term “examination” used in this specification should be expansively construed to cover any kind of operations related to defect detection, defect review and/or defect classification of various types, segmentation, and/or metrology operations during and/or after the specimen fabrication process (also referred to as the manufacturing process). Examination is provided by using non-destructive examination tools during or after manufacture of the specimen to be examined. By way of non-limiting example, the examination process can include runtime scanning (in a single or in multiple scans), imaging, sampling, detecting, reviewing, measuring, classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination” or its derivatives used in this specification are not limited with respect to resolution or size of an inspection area. A variety of non-destructive examination tools includes, by way of non-limiting example, scanning electron microscopes (SEM), atomic force microscopes (AFM), optical inspection tools, etc.

The term “metrology operation” used in this specification should be expansively construed to cover any metrology operation procedure used to extract metrology information relating to one or more structural elements on a semiconductor specimen. In some embodiments, the metrology operations can include measurement operations, such as, e.g., critical dimension (CD) measurements performed with respect to certain structural elements on the specimen, including but not limiting to the following: dimensions (e.g., line widths, line spacing, contact diameters, size of the element, edge roughness, gray level statistics, etc.), shapes of elements, distances within or between elements, related angles, overlay information associated with elements corresponding to different design levels, etc. Measurement results such as measured images are analyzed, for example, by employing image-processing techniques. Note that, unless specifically stated otherwise, the term “metrology” or derivatives thereof used in this specification, are not limited with respect to measurement technology, measurement resolution, or size of inspection area.

The term “defect” used in this specification should be expansively construed to cover any kind of abnormality or undesirable feature/functionality formed on a specimen. In some cases, a defect may be a defect of interest (DOI) which is a real defect that has certain effects on the functionality of the fabricated device, thus is in the customer's interest to be detected. For instance, any “killer” defects that may cause yield loss can be indicated as a DOI. In some other cases, a defect may be a nuisance (also referred to as “false alarm” defect) which can be disregarded because it has no effect on the functionality of the completed device and does not impact yield.

The term “design data” used in the specification should be expansively construed to cover any data indicative of hierarchical physical design (layout) of a specimen. Design data can be provided by a respective designer and/or can be derived from the physical design (e.g., through complex simulation, simple geometric and Boolean operations, etc.). Design data can be provided in different formats, as, by way of non-limiting examples, GDSII format, OASIS format, etc. Design data can be presented in vector format, grayscale intensity image format, or otherwise.

The term “image(s)” or “image data” used in the specification should be expansively construed to cover any original images/frames of the specimen captured by an examination tool during the fabrication process, derivatives of the captured images/frames obtained by various pre-processing stages, and/or computer-generated synthetic images (in some cases based on design data). Depending on the specific way of scanning (e.g., one-dimensional scan such as line scanning, two-dimensional scan in both x and y directions, or dot scanning at specific spots, etc.), image data can be represented in different formats, such as, e.g., as a gray level profile, a two-dimensional image, or discrete pixels, etc. It is to be noted that in some cases the image data referred to herein can include, in addition to images (e.g., captured images, processed images, etc.), numeric data associated with the images (e.g., metadata, hand-crafted attributes, etc.). It is further noted that images or image data can include data related to a processing step/layer of interest, or a plurality of processing steps/layers of a specimen.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately or in any suitable sub-combination. In the following detailed description, numerous specific details are set forth in order to provide a thorough understanding of the methods and apparatus.

The process of semiconductor manufacturing often requires multiple sequential processing steps and/or layers, each one of which could possibly cause errors that may lead to yield loss. Examples of various processing steps can include lithography, etching, depositing, planarization, growth (such as, e.g., epitaxial growth), and implantation, etc. Various examination operations, such as defect-related examination, and/or metrology-related examination, can be performed at different processing steps/layers during the manufacturing process to monitor and control the process. The examination operations can be performed a multiplicity of times, for example after certain processing steps, and/or after the manufacturing of certain layers, or the like.

As described above, various types of examination tools can be used for performing examination of a semiconductor specimen, such as, e.g., optical inspection tools, electron beam tools, etc. By way of example, scanning electron microscopes (SEM) is a type of electron microscope that produces images of a specimen by scanning the specimen with a focused beam of electrons. SEM is capable of accurately inspecting and measuring features during the manufacture of semiconductor wafers. The electrons interact with atoms in the specimen, producing various signals that contain information on the surface topography and/or composition of the specimen.

Specifically, when an electron beam strikes a specimen, different types of signals are generated. Secondary electrons (SEs) originate from the surface or the near-surface regions of the specimen. They are a result of inelastic interactions between the primary electron beam and the specimen, and have lower energy. Specifically, SEs are produced when an incident electron excites an electron in the specimen and loses some of its energy in the process. The excited electron moves towards the surface of the specimen and, if it still has sufficient energy, it escapes from the surface as a secondary electron. The shallow depth of production of detected SEs makes them ideal for examining topography of the specimen's surface.

Additionally, backscattered electrons (BSEs) are reflected back after elastic interactions between the beam and the specimen. This type of electrons originates from a broader and deeper region within the interaction volume in the specimen. They are a result of elastic scattering of electrons with atoms, which result in a change in the electrons' trajectory. Specifically, when the electron beam strikes the specimen, some of the electrons are deflected from their original path by atoms in the specimen in an elastic fashion. These essentially elastically scattered primary electrons (which are high-energy electrons) that rebound from the sample, are referred to as BSEs.

BSEs and SEs can be collected by different detectors of the SEM tool. As described, BSEs come from deeper regions of the sample, while SEs originate from surface regions. Therefore, BSEs and SEs carry different types of information. For instance, images generated based on BSEs show high sensitivity to differences in atomic number, therefore can carry information on the specimen's interior structure and/or composition (i.e., this is referred to as the see-through ability of the BSEs to probe the specimen in depth when provided with enough landing energy), whereas images generated based on SEs can provide more detailed surface information.

As semiconductor processes progress, semiconductor devices are developed with increasingly complex three-dimensional structures which have deeper layers and various material compositions. When examining a semiconductor specimen having multiple layers, the electron yield from the specimen, such as the BSEs, represents an overall response of the beam from all penetrated layers.

During examination, when a signal (representative of, e.g., a measurement from the SEM image) demonstrates potential presence of a defect buried in a specimen, it is difficult to identify the actual depth of such a defect within the specimen (e.g., at which layer or processing step the defect occurs), since the signal is produced based on the overall BSE response from all the penetrated layers of the specimen, where each layer has its respective structural properties such as, e.g., geometrical properties and/or material properties, whose actual values are unknown.

For purposes of estimating the actual depth of the defect, in some cases the specimen has to be destroyed using destructive measures such as Xsection, by a destructive tool like TEM, which requires resources and is time-consuming. In some cases, a technique called “Landing energy (LE) sweep” can be used, where the specimen is scanned multiple times using different levels of LE, giving rise to multiple measurement signals. The depth of the buried defect can be determined based on the level of LE at which the peak of the measurement signals is obtained.

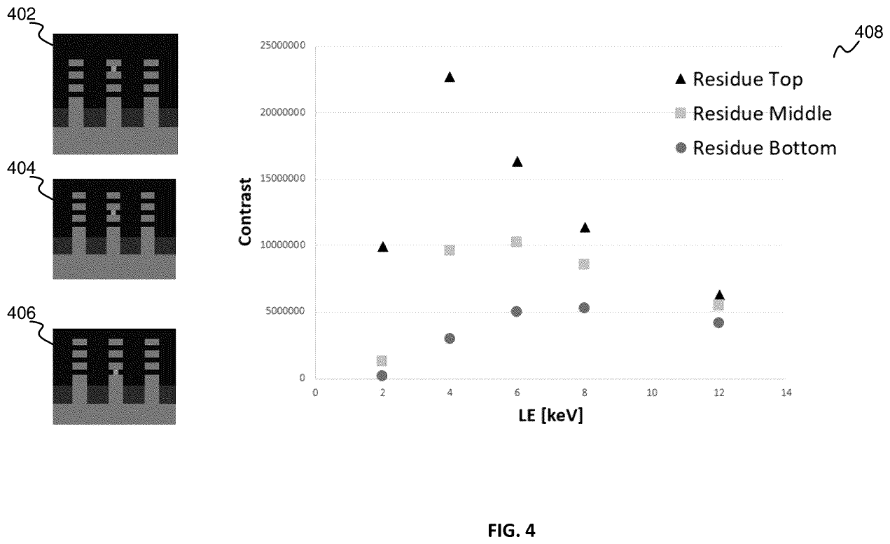

FIG. 4 illustrates a schematic graph of measurements obtained at different levels of LEs for a defect located at different depths of a specimen in accordance with certain embodiments of the presently disclosed subject matter.

The exemplary specimen in FIG. 4 is a Gate-all-around (GAA) transistor where the gate can come into contact with the channel on all sides. The defect is illustrated as a SiGe residue which remains after the etching processing step. Due to the GAA structure, the residue can be possibly located at different layers of the specimen, as illustrated in the cross-section views 402 (where the residue is located at the top etching layer, illustrated as a gap layer), 404 (where the residue is located at the middle etching layer) and 406 (where the residue is located at the bottom etching layer) of the specimen.

The graph 408 illustrates the measurements obtained at different levels of LEs in cases where the residue is located at the top, middle, and bottom etching layer of the specimen. Y axis illustrates the measurements represented in the form of contrast obtained from the acquired images, and X axis illustrates a sequence of LEs ranging between 2 keV-12 keV. Graph 408 can be constructed based on experimental or historical measurement data of GAA structures. As shown, when the residue is located at the top etching layer (also referred to as top residue), the peak of the contrast measurements (denoted by triangles) appears at LE of 4 keV. When the residue is located at the middle etching layer (also referred to as middle residue), the peak of the contrast measurements (denoted by squares) appears at LE of 6 keV. When the residue is located at the bottom etching layer (also referred to as bottom residue), the peak of the contrast measurements (denoted by circles) appears at LE of 8 keV.

Based on this experimental knowledge, during examination, when scanning a GAA specimen multiple times using the sequence of LEs, the depth of the residue can be determined based on the level of LE at which the peak of the measurements is obtained. For instance, if the peak appears at LE of 4 keV, it can be determined that the residue is located at the top gapped layer, whereas if the peak appears at LE of 8 keV, it can be determined that the residue is located at the bottom gapped layer.

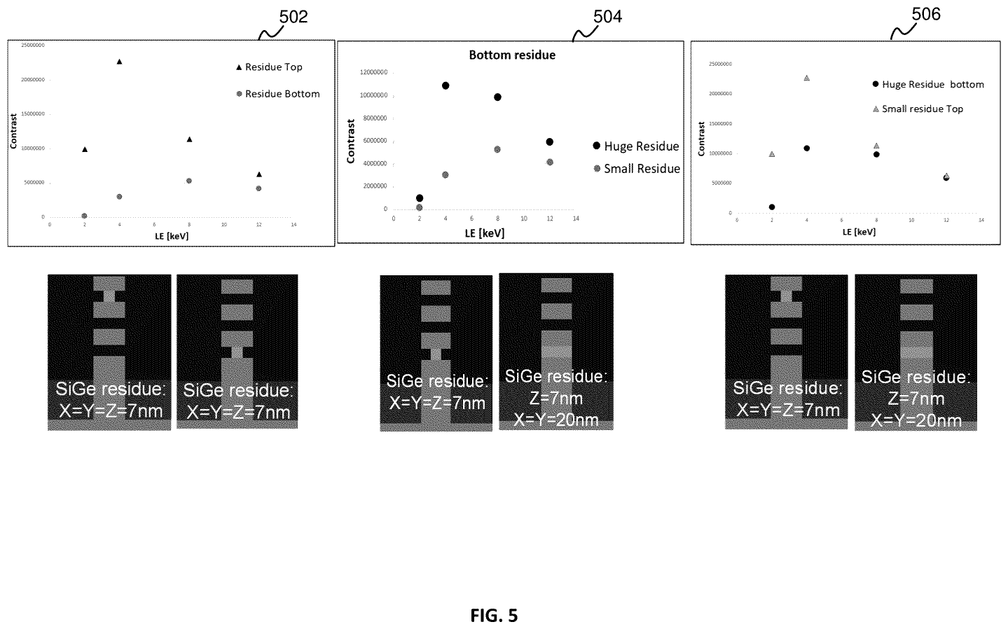

However, this method requires to switch between different LEs and scan the specimen multiple times, which significantly affects system throughput (TpT). In addition, the method does not always provide reliable depth estimation, since the LE at which the peak of measurements appears depends on not only defect depth, but also defect size. FIG. 5 illustrates a few examples of such cases in accordance with certain embodiments of the presently disclosed subject matter.

Graph 502 illustrates that in cases of a residue of a fixed size (x=y=z=7 nm), the depth of the residue can be determined as described above, based on the level of LE at which the peak of the measurements is obtained. As shown, the top residue corresponds to a peak measurement at LE of 4 keV, while the bottom residue corresponds to a peak measurement at LE of 8 keV.

Graph 504 illustrates two bottom residues having different sizes (e.g., the small residue with a dimension of x=y=2=7 nm, while the large residue (denoted as “huge residue” in the figure) with a dimension of x=y=20 nm and z=7 nm). As shown, although the two residues reside at the same depth, their peak measurements are obtained at different LEs due to the size variation, e.g., the small bottom residue corresponds to a peak measurement at LE of 8 keV, while the large bottom residue corresponds to a peak measurement at LE of 4 keV. Therefore, in such cases, the experimental knowledge gained from graph 408 is no longer reliable, as it cannot be determined for sure that in cases of a peak measurement obtained at 4 keV, the residue is always located at the top layer.

Graph 506 illustrates a top residue having a small size (x=y=z=7 nm) as compared to a bottom residue having a large size (x=y=20 nm, z=7 nm). As shown, although the two residues reside at different depths, their peak measurements are obtained at the same LE(4 keV). This further demonstrates that the defect depth cannot be simply determined based on the level of LE at which the peak of the measurements is obtained.

Accordingly, certain embodiments of the presently disclosed subject matter propose a system and method for depth estimation of a defect buried in a semiconductor specimen, which do not have one or more of the disadvantages described above. The present disclosure proposes to estimate the depth of a buried defect based on a single scan of the specimen using one LE, and select an optimal EE corresponding to the LE, at which the BSEs should be collected. Using the measurement obtained based on the BSEs collected as such, the depth of the buried defect can be directly deduced, as will be detailed below.

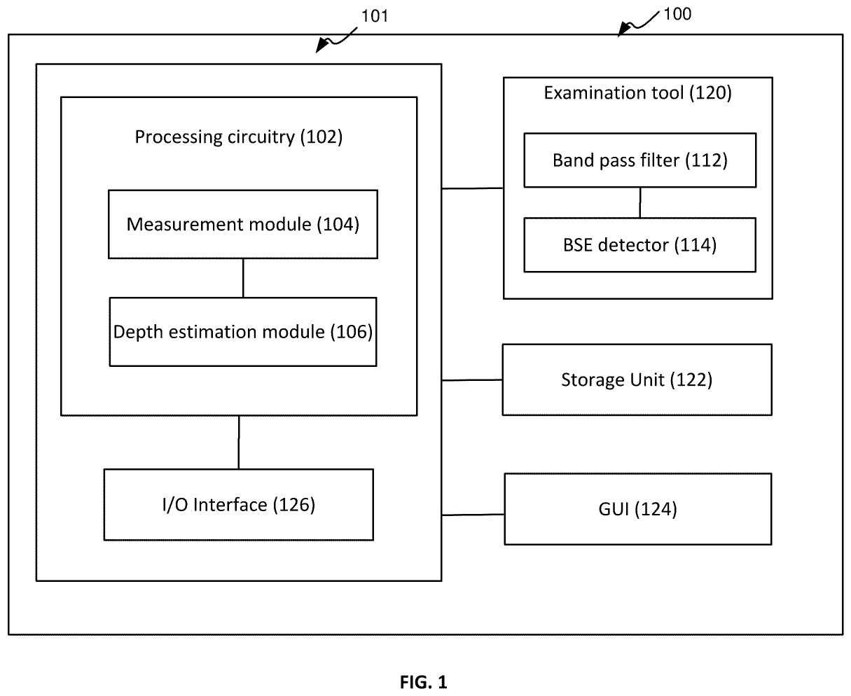

Bearing this in mind, attention is drawn to FIG. 1 illustrating a functional block diagram of an examination system in accordance with certain embodiments of the presently disclosed subject matter.

The examination system 100 illustrated in FIG. 1 can be used for examination of a semiconductor specimen (e.g., a wafer, a die, or parts thereof) as part of the specimen fabrication process. As described above, the examination referred to herein can be construed to cover any kind of operations related to defect inspection/detection, defect review, defect classification, segmentation, and/or metrology operations, such as, e.g., metrology measurements, etc., with respect to the specimen. System 100 comprises one or more examination tools 120 configured to scan a specimen and capture images thereof to be further processed for various examination applications.

The term “examination tool(s)” used herein should be expansively construed to cover any tools that can be used in examination-related processes, including, by way of non-limiting example, scanning, imaging, sampling, reviewing, measuring, classifying, and/or other processes provided with regard to the specimen or parts thereof. The examination tools 120 can be implemented as machines of various types. In some embodiments, the examination tool can be implemented as an electron beam machine/tool, such as e.g., Scanning Electron Microscope (SEM) as described above, Atomic Force Microscopy (AFM), or Transmission Electron Microscope (TEM), etc.

According to certain embodiments, the examination tool 120 can include one or more inspection tools and/or one or more review tools. The inspection tools can scan the specimen to capture inspection images and detect potential defects in accordance with a defect detection algorithm. The output of the detection module is a defect map indicative of defect candidate distribution on the semiconductor specimen. The review tools can be configured to capture review images at locations of the defect candidates in the map, and review the review images for ascertaining whether a defect candidate is indeed a DOI. In some cases, at least one of the examination tools 120 has metrology capabilities. Such an examination tool is also referred to as a metrology tool. The metrology tool can be configured to generate image data in response to scanning the specimen, and perform metrology operations based on the image data.

In some cases, the same examination tool can provide low-resolution image data and high-resolution image data. The resulting image data can be transmitted—directly or via one or more intermediate systems—to system 101. The present disclosure is not limited to any specific type of examination tools and/or the representation/resolution of image data resulting from the examination tools.

According to certain embodiments of the presently disclosed subject matter, the examination system 100 comprises a computer-based system 101 operatively connected to the examination tools 120 and capable of depth estimation of a defect buried in a semiconductor specimen in runtime during specimen fabrication, as will be detailed below. System 101 is also referred to as a defect depth estimation system.

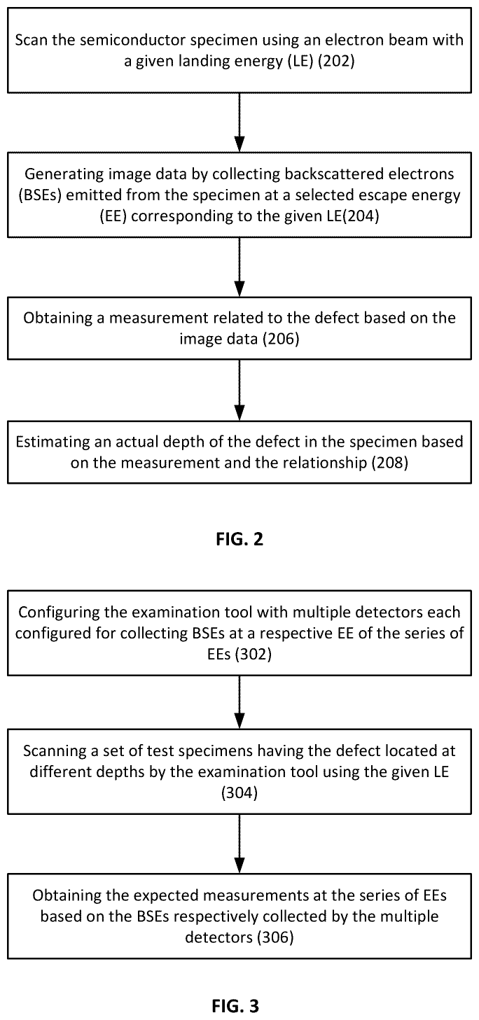

System 101 includes a processing circuitry 102 operatively connected to a hardware-based I/O interface 126 and configured to provide processing necessary for operating the system, as further detailed with reference to FIGS. 2-3. The processing circuitry 102 can comprise one or more processors (not shown separately) and one or more memories (not shown separately). The one or more processors of the processing circuitry 102 can be configured to, either separately or in any appropriate combination, execute several functional modules in accordance with computer-readable instructions implemented on a non-transitory computer-readable memory comprised in the processing circuitry. Such functional modules are referred to hereinafter as comprised in the processing circuitry.

The one or more processors referred to herein can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

One or more functional modules comprised in the processing circuitry 102 of system 101 can include a measurement module 104 and a depth estimation module 106 that can be operatively connected to each other. Specifically, the examination tool 120 (e.g., an electron beam tool) can be configured to scan the semiconductor specimen using an electron beam with a given landing energy (LE), and generate image data by collecting backscattered electrons (BSEs) emitted from the specimen at a selected escape energy (EE) corresponding to the given LE. The selected EE can be determined based on a relationship representative of expected measurements obtained at a series of EEs corresponding to the given LE for different expected depths of the defect in the specimen.

Upon receiving the image data from the examination tool 120, the measurement module 104 can be configured to obtain a measurement related to the defect based on the image data. The depth estimation module 106 can be configured to estimate an actual depth of the defect in the specimen based on the measurement and the relationship.

In order to enable the examination tool to collect BSEs at a specific EE such as the selected EE, the examination tool 120 can be configured with a band pass filter 112 which is operatively connected to the BSE detector(s) 114 and capable of filtering out BSEs emitted at other EEs and enables the BSE detector(s) to collect the BSEs only at the selected EE.

Operation of systems 100 and 101, the processing circuitry 102, and the functional modules therein will be further detailed with reference to FIGS. 2-3.

It is to be noted that while certain embodiments of the present disclosure refer to the processing circuitry 102 being configured to perform the above recited operations, the functionalities/operations of the aforementioned functional modules can be performed by the one or more processors in processing circuitry 102 in various ways. By way of example, the operations of each functional module can be performed by a specific processor, or by a combination of processors. The operations of the various functional modules, such as obtaining the measurement, and estimating the actual depth of the defect, etc., can thus be performed by respective processors (or processor combinations) in the processing circuitry 102, while, optionally, these operations may be performed by the same processor. The present disclosure should not be limited to being construed as one single processor always performing all the operations.

In some cases, additionally to system 101, the examination system 100 can comprise one or more examination modules, such as, e.g., metrology operation module, defect detection module, Automatic Defect Review Module (ADR), Automatic Defect Classification Module (ADC), and/or other examination modules which are usable for examination of a semiconductor specimen. The one or more examination modules can be implemented as stand-alone computers, or their functionalities (or at least part thereof) can be integrated with the examination tool 120. In some cases, the output of system 101, e.g., the estimated depth of the defect, can be provided to the one or more examination modules for further processing.

According to certain embodiments, system 100 can comprise a storage unit 122. The storage unit 122 can be configured to store any data necessary for operating system 101, e.g., data related to input and output of system 101, as well as intermediate processing results generated by system 101. By way of example, the storage unit 122 can be configured to store image data of the specimen and/or derivatives thereof produced by the examination tool 120. Accordingly, these input data can be retrieved from the storage unit 122 and provided to the processing circuitry 102 for further processing. The output of the system 101, such as the estimated depth of the defect, can be sent to storage unit 122 to be stored.

In some embodiments, system 100 can optionally comprise a computer-based Graphical User Interface (GUI) 124 which is configured to enable user-specified inputs related to system 101. For instance, the user can be presented with a visual representation of the specimen (for example, by a display forming part of GUI 124), including image data of the specimen, etc. The user may be provided, through the GUI, with options of defining certain operation parameters. The user may also view the operation results or intermediate processing results, such as, e.g., the estimated depth of the defect, etc., on the GUI.

In some cases, system 101 can be further configured to send the output to the storage unit 122, and/or external systems (e.g., yield management system (YMS) of a fabrication plant (FAB)) for controlling a processing step of the fabrication process that is related to the root cause. A yield management system (YMS) in the context of semiconductor manufacturing is a data management, analysis, and tool system that collects data from the FAB, especially during manufacturing ramp ups, and helps engineers find ways to improve yield. YMS helps semiconductor manufacturers and FABs manage high volumes of production analysis with fewer engineers. These systems analyze the yield data and generate reports. YMS can be used by Integrated Device Manufacturers (IMD), FABs, fabless semiconductor companies, and Outsourced Semiconductor Assembly and Test (OSAT).

Those versed in the art will readily appreciate that the teachings of the presently disclosed subject matter are not bound by the system illustrated in FIG. 1. Each system component and module in FIG. 1 can be made up of any combination of software, hardware and/or firmware, as relevant, executed on a suitable device or devices, which perform the functions as defined and explained herein. Equivalent and/or modified functionality, as described with respect to each system component and module, can be consolidated or divided in another manner. Thus, in some embodiments of the presently disclosed subject matter, the system may include fewer, more, modified and/or different components, modules and functions than those shown in FIG. 1.

Each component in FIG. 1 may represent a plurality of the particular component, which are adapted to independently and/or cooperatively operate to process various data and electrical inputs, and for enabling operations related to a computerized examination system. In some cases, multiple instances of a component may be utilized for reasons of performance, redundancy, and/or availability. Similarly, in some cases, multiple instances of a component may be utilized for reasons of functionality or application. For example, different portions of the particular functionality may be placed in different instances of the component.

It should be noted that the examination system illustrated in FIG. 1 can be implemented in a distributed computing environment, in which one or more of the aforementioned components and functional modules shown in FIG. 1 can be distributed over several local and/or remote devices. By way of example, the examination tool 120 and the system 101 can be located at the same entity (in some cases hosted by the same device) or distributed over different entities, depending on specific system configurations and implementation needs. In some examples, certain components utilize a cloud implementation, e.g., implemented in a private or public cloud. Communication between the various components of the examination system, in cases where they are not located entirely in one location or in one physical entity, can be realized by any signaling system or communication components, modules, protocols, software languages and drive signals, and can be wired and/or wireless, as appropriate.

It should be further noted that in some embodiments at least some of examination tools 120, storage unit 122 and/or GUI 124 can be external to the examination system 100 and operate in data communication with systems 100 and 101 via I/O interface 126. System 101 can be implemented as stand-alone computer(s) to be used in conjunction with the examination tools, and/or with the additional examination modules as described above. Alternatively, the respective functions of the system 101 can, at least partly, be integrated with one or more examination tools 120, thereby facilitating and enhancing the functionalities of the examination tools 120 in examination-related processes.

While not necessarily so, the process of operation of systems 101 and 100 can correspond to some or all of the stages of the methods described with respect to FIGS. 2-3. Likewise, the methods described with respect to FIGS. 2-3 and their possible implementations can be implemented by systems 101 and 100. It is therefore noted that embodiments discussed in relation to the methods described with respect to FIGS. 2-3 can also be implemented, mutatis mutandis, as various embodiments of the systems 101 and 100, and vice versa.

Referring to FIG. 2, there is illustrated a generalized flowchart of estimating the depth of a defect buried in a semiconductor specimen in accordance with certain embodiments of the presently disclosed subject matter.

As described above, a semiconductor specimen is typically made of multiple layers. The examination process of a specimen can be performed a multiplicity of times during the fabrication process of the specimen, for example following the processing steps of specific layers. In some cases, a sampled set of processing steps can be selected for in-line examination, based on their known impacts on device characteristics or yield. Images of the specimen or parts thereof can be acquired at the sampled set of processing steps to be examined.

For the purpose of illustration only, certain embodiments of the following description are described with respect to a given processing step/layer of the sampled set of processing steps. Those skilled in the art will readily appreciate that the teachings of the presently disclosed subject matter, such as the process disclosed herein for purpose of defect depth estimation, can be performed following any layer and/or processing steps of the specimen. The present disclosure should not be limited to the number of layers comprised in the specimen and/or the specific layer(s) to be examined.

The specimen can be irradiated with an electron beam having a given landing energy. The output radiation emanating from the specimen, e.g., the BSEs emitted from the specimen in response to the irradiation, can be collected by one or more BSE detectors of the e-beam tool. As described above, since the semiconductor specimen has multiple layers, for an electron beam with a given LE, the BSEs are emitted from different penetrated layers of the specimen with different escape energies (EE) (i.e., the energy levels of the electrons when they escape from the specimen). Currently, the BSE detectors collect all BSE yield from the specimen which represents an overall response of the beam from all penetrated layers. Therefore, the measurement from a single scan cannot identify the actual depth of a defect buried within the specimen. As described above, in some cases a technique called “Landing energy (LE) sweep” is used, where the specimen is scanned multiple times using different levels of LE, and the depth of the buried defect can be determined based on the level of LE at which the peak of the measurement signals is obtained. As aforementioned, this method suffers from low throughput (TpT) due to multiple scanning, as well as error-prone estimation results, since the LE of the peak measurement depends on not only defect depth, but also defect size.

The present disclosure proposes to scan the specimen once only using a single LE and select an optimal EE corresponding to the LE, at which the BSEs should be collected. Using the measurement obtained from the image data generated based on the BSEs collected as such, the depth of the buried defect can be directly deduced.

Specifically, the semiconductor specimen can be scanned (202) (e.g., by the examination tool 120 such as an e-beam tool) using an electron beam with a given landing energy (LE). In response to such scanning, image data can be generated (204) by collecting backscattered electrons (BSEs) emitted from the specimen at a specific escape energy (EE) corresponding to the given LE. A semiconductor specimen here can refer to a semiconductor wafer, a die, or parts thereof, that is fabricated and examined in the fab during a fabrication process thereof. The specimen can be scanned at a target area or a target structure that is of interest to be examined on the specimen. For instance, the target area can be defined as an area that contains the defect as detected. As described above, the image data can be represented in various forms, such as, e.g., a gray level profile represented by a waveform signal, a two-dimensional image, or discrete pixels, etc., depending on the specific way of scanning and image processing.

A measurement related to the defect can be obtained (206) (e.g., by the measurement module 104 in the processing circuitry 102) based on the image data and an actual depth of the defect in the specimen can be estimated (208) (e.g., by the depth estimation module 106 in the processing circuitry 102) based on the measurement and the relationship. By way of example, the term “measurement” used herein can refer to any type of measurement data that can be derived from the image data, including but not limited to, e.g., a measurement signal representative of the amount of collected BSEs, SNR of the signal, a contrast measurement indicative of the range/difference of color or brightness in an image, a CD measurement, etc.

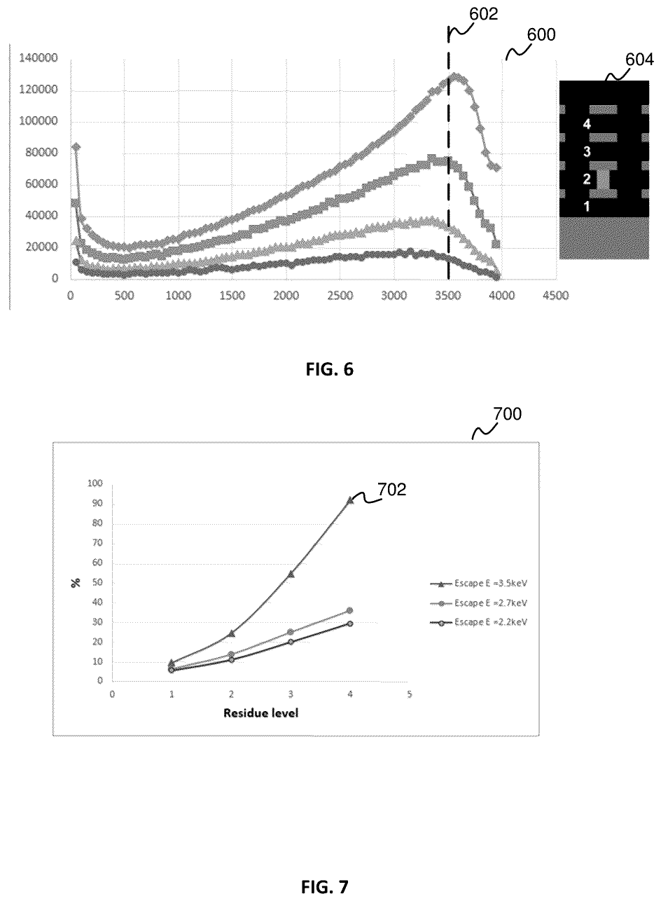

Specifically, the specific EE, also referred to as an optimal EE, or a selected LE, can be selected from a series of EEs corresponding to the given LE based on a relationship representative of expected measurements obtained at the series of EEs for different expected depths of the defect in the specimen. Referring now to FIG. 6, there is illustrated an exemplary GAA structure with four possible depth levels for a residue defect, and an exemplary graph demonstrating the relationships between expected measurements and a series of EEs for the four different depth levels in accordance with certain embodiments of the presently disclosed subject matter.

As shown, the exemplified GAA structure 604 has four etching layers where a residue defect can possibly be located, denoted as 1-4 in the figure. The graph 600 has an X axis representing a series of different EEs corresponding to a given LE of 4 keV, and a Y axis representing expected measurements (exemplified by the amount of collected BSEs in the present example). The graph 600 includes four waveforms, each corresponding to a respective depth level of the four possible depths 1-4, as illustrated in the GAA structure 604. Each waveform demonstrates a function/relationship representative of the expected measurements obtained at the series of EEs for a respective depth of the defect in the GAA structure.

Such relationship waveforms can be constructed in different ways. By way of example, in some cases, it can be created by performing simulation of the expected measurements based on material and structural properties of the semiconductor specimen. For instance, the relationship between the expected measurements and the series of EEs for a specific depth can be derived using physical parameterizations of measurements or Monte Carlo simulation based on the physical properties (e.g., material and structural properties) of the specimen. Take the GAA structure 604 as an example, the GAA structure comprises multiple SiGe and Si layers. For a residue defect that resides at a given depth among the depth levels 1-4, a function can be defined based on the correlation between the measurements obtained at different EEs and the physical properties of the layers. Therefore, four functions can be defined corresponding to the four possible depths 1-4 of the defect, and the four waveforms illustrated in FIG. 4 represent such four functions.

By way of another example, alternative to simulation, the relationship can be derived by actual experiments. FIG. 3 illustrates a generalized flowchart of deriving the relationship between the expected measurements and the series of EEs for different defect depths in the specimen based on experiments in accordance with certain embodiments of the presently disclosed subject matter.

As shown, the examination tool can be configured (302) with multiple BSE detectors, each configured for collecting BSEs at a respective EE of the series of EEs. Unlike conventional tool configuration, where the BSE detectors are configured to collectively gather all the BSE yield from the specimen, the proposed configuration enables the tool to separately collect BSEs emitted with different EEs. A set of test specimens having the defect located at different depths can be scanned (304) by the examination tool using the given LE. For experimental purposes, the set of test specimens can be fabricated specifically to have an intended defect located at different depths. For instance, the set of test specimens can include four specimens, each having a residue defect located at one of the four possible depths in the GAA layers. In response to scanning, the expected measurements at the different EEs can be obtained (306) based on the BSEs respectively collected by the multiple detectors.

Referring back to FIG. 6, it is shown that the largest separation between the expected measurements of the four waveforms appears around the EE of 3.5 keV, as illustrated by the dash line 602. The EE of 3.5 keV can thus be selected as the optimal EE corresponding to the given LE of 4 keV, which is used for collecting the BSEs at such a specific EE, and obtaining the measurements therefrom. The measurement obtained at the optimal EE is used to estimate the depth of the defect based on the relationship as illustrated in graph 600, as there is a higher probability of successfully separating the measurements resulting from different defect depths at this EE, thus providing an accurate depth estimation.

By way of example, in cases where the obtained measurement is within or close to the range of 120000-140000 BSEs or the equivalent thereof, it can be determined (with relatively high confidence and accuracy), based on the expected measurements obtained along the line 602 in FIG. 6, that the depth of the defect is likely to be at the top layer (i.e., layer 4). Due to the relatively large separation at the optimal EE, it is unlikely to incorrectly determine the depth of the defect based on the measurement, even if taking into consideration the measurement variations due to, e.g., process variation or color variations, etc. It is to be noted that although it is exemplified above that the optimal EE is selected as the EE that provides the largest separation between the expected measurements, this is for illustrative and exemplary purposes only, and should not be regarded as limiting the present disclosure in any way. In some cases, an EE that provides a relatively large separation (e.g., relative to the separation of a certain percentage of the series of EEs) between the expected measurements, can be selected as the optimal EE. For instance, an EE that provides a separation larger than 90% of the EEs in the series of EEs, can be selected as the optimal EE to be used for BSE collection and image data generation. In such cases, any EE within the range of EEs that provides the 10% largest separation, can be selected and used.

FIG. 7 shows another graph illustrating the relationship between the measurements for different depth levels at multiple EEs in accordance with certain embodiments of the presently disclosed subject matter.

As shown, graph 700 illustrates the relationship from a different perspective, where the X axis represents the depth levels of the residue defect (e.g., representing the four possible depths 1-4 as illustrated in the GAA structure 604), and the Y axis represents the expected measurements (exemplified as SNR of the measurement signal in the present example). The graph 700 includes three lines, each corresponding to a respective EE in the series of EEs corresponding to the LE of 4 keV. Each line demonstrates a function/relationship representative of the expected measurements for different depth levels obtained at a respective EE.

For instance, line 702 illustrates the relationship representative of the expected measurements for the four depth levels obtained at the EE of 3.5 keV. As shown, compared to the other two relationships corresponding to the EE of 2.7 keV and 2.2 keV, line 702 has the largest derivative (i.e., steepest slope), representing fast changes of measurement values (i.e., large separation) between the four depth levels. Therefore, graph 700 demonstrates, from another perspective, that the EE of 3.5 keV provides the largest separation (as compared to the EE of 2.7 keV and 2.2 keV), thus can be selected as the optimal EE to be used.

In some embodiments, the optimal EE for a given LE used to scan a given specimen can be pre-selected during a setup phase, based on the relationship as described above. The selected EE can then be used for runtime examination of specimens during their fabrication process. In some cases, the given LE can be predefined, or selected, as will be described below in further detail.

As described above, the BSE detectors in the conventional e-beam tool collect all BSE yield from the specimen which represents an overall response of the beam from all penetrated layers. According to certain embodiments of the present disclosure, the examination tool needs to be specifically configured in order to be able to collect BSEs at a specific EE such as the selected EE. By way of example, the examination tool can be configured by adding a band pass filter operatively connected to the BSE detector(s). The band pass filter is configured to filter out BSEs emitted at other EEs and enable the BSE detector(s) to collect the BSEs only at the selected EE.

According to certain embodiments, the given LE used to scan a given specimen can be pre-selected from a set of possible LEs. By way of example, a set of relationships can be derived corresponding to the set of LEs, in a similar manner as described above, e.g., using simulation and/or experiments. The given LE can be selected as the LE whose optimal EE provides the best separation between the expected measurements for the different expected depths of the defect.

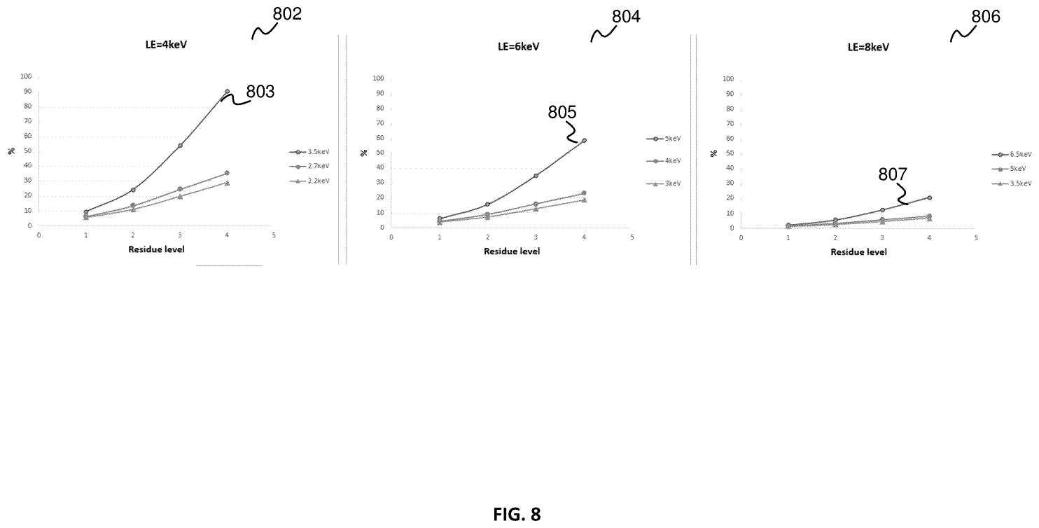

Referring to FIG. 8, there are shown a few graphs illustrating a set of relationships derived corresponding to a set of LEs for a GAA structure in accordance with certain embodiments of the presently disclosed subject matter.

The graph 802 is similar to graph 700 in FIG. 7, illustrating the relationship between the expected measurements for different depth levels of the residue defect at three EEs, corresponding to the LE of 4 keV. As described above, line 803, corresponding to the EE of 3.5 keV, has the largest derivative, representing fast changes of measurement values (i.e., largest separation of measurements) between the four depth levels. Therefore, the optimal EE for LE of 4 keV is selected as 3.5 keV.

Similarly, graph 804 illustrates the relationship derived for the LE of 6 keV, where the optimal EE that can provide the largest separation is 5 keV, as illustrated by line 805. Graph 806 illustrates the relationship derived for the LE of 8 keV, where the optimal EE that can provide the largest separation is 6.5 keV, as illustrated by line 807. Comparing the three lines 803, 805, and 807 corresponding to three selected optimal EEs for the three LEs, it can be seen that line 803 provides the best separation between the expected measurements for the four depth levels. Therefore, the LE to be used for the GAA specimen is selected as 4 keV, and the corresponding optimal EE thereof is 3.5 keV. Similarly, these relationships can be derived in different ways, such as via simulation and/or experiments, as described above. The selected LE and the optimal EE thereof form a pair of selected LE and EE to be used for scanning GAA specimens.

It is to be noted that the above exemplary pair of LE and EE is selected with respect to a specific structure of GAA. For different specimens with different structures, different pairs of LE and EE can be selected in a similar manner and used for purposes of scanning and depth estimation.

Using the selected pair of LE and EE, the specimen only needs to be scanned once using the LE, and the depth of the defect buried in the specimen can be estimated based on the measurement derived from the BSEs collected at the selected EE. Such depth estimation has improved throughput and accuracy with respect to estimation based on measurements obtained by scanning the specimen multiple times using multiple LEs, such as using the technique of “LE sweeping” as described above.

The presently proposed depth estimation can be applicable to any type of specimen having a buried defect. By way of example, in some cases, the specimen can comprise multiple layers, and the defect is expected to be located at a set of candidate layers of the multiple layers, such as the exemplified GAA structure described above, where the defect is a residue expected to be located at a plurality of etching layers. In some other cases, the specimen can consist of a single layer, and the defect can be expected to be located at different depth levels in the single layer.

It is to be noted that the above examples of selecting the optimal EE, or selecting the pair of LE and EE, are illustrated for exemplary purposes, and should not be regarded as limiting the present disclosure in any way. Other ways of selection can be implemented in addition to or in lieu of the above. By way of example, in some cases, the LE and EE can be selected based on machine learning (ML). For instance, a ML model can be trained using a training set comprising a plurality of training images acquired for a semiconductor specimen with a given structure (such as, e.g., a GAA structure). The training images capture the specimen with a defect buried at different depths. Each training image is associated with a pair of EE and LE that is used to acquire the image, and an actual depth of the defect thereof. Taking the GAA structure as an example, for each specific defect depth, three LEs can be used to scan the specimen, and three EEs can be used to collect BSEs, thereby giving rise to nine images captured at different LE and EE configurations corresponding to the specific defect depth.

The ML model can be trained to process the training images and predict the optimal LE and EE that should be used to scan the specimen and obtain the image data for defect depth estimation. The ML model, once trained, can be used to indicate which pair of LE and EE to select for a given specimen to be examined, and, upon receiving a given image, can provide estimate defect depth. It is to be noted that different ML models can be trained using different training sets for different specimen structures. Alternatively, a ML model can be retrained to be adapted to different specimen structures.

The estimated depth can be used for the purpose of process control, such as, e.g., modifying a processing step in the fabrication process that is related to the layer of the defect. For instance, the processing step of the identified layer can be investigated, and measures can be taken to adjust/optimize the processing step, thus eliminating future defectivity.

It is to be noted that the examples and embodiments illustrated in the present disclosure, such as, e.g., the examples of semiconductor specimens, the exemplary LEs and EEs, the waveforms and line charts, etc., are illustrated for exemplary purposes, and should not be regarded as limiting the present disclosure in any way. Other appropriate examples/implementations can be used in addition to, or in lieu of the above.

Among advantages of certain embodiments of the presently disclosed subject matter as described herein is to be able to estimate the depth of a buried defect in a specimen by scanning the specimen once using a single LE, and collecting the BSEs at an optimal EE corresponding to the LE. Using the measurement obtained based on the BSEs collected as such, the depth of the buried defect can be directly deduced.

The proposed depth estimation can significantly improve system throughput, as it requires only a single scan, thus reducing tool time for switching between different LEs and multiple scanning of the specimen, as required in conventional “LE sweeping” methodology.

In addition, the proposed method can provide estimated depth with improved accuracy by using a selected pair of LE and EE (e.g., selecting an optimal EE for a given LE, or selecting both the LE and EE, as described above), which provides best separation between the expected measurements for different defect depths, and makes it unlikely to incorrectly determine the depth of the defect based on the measurement, even if taking into consideration measurement variations due to, e.g., process variation or color variations, etc.

It is to be understood that the present disclosure is not limited in its application to the details set forth in the description contained herein or illustrated in the drawings.

It will also be understood that the system according to the present disclosure may be, at least partly, implemented on a suitably programmed computer. Likewise, the present disclosure contemplates a computer program being readable by a computer for executing the method of the present disclosure. The present disclosure further contemplates a non-transitory computer-readable memory tangibly embodying a program of instructions executable by the computer for executing the method of the present disclosure.

The present disclosure is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the present disclosure as hereinbefore described without departing from its scope, defined in and by the appended claims.

1. A computerized system of examining a defect buried in a semiconductor specimen, the system comprising:
an examination tool configured to scan the semiconductor specimen using an electron beam with a given landing energy (LE), and generate image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and
a processing circuitry operatively connected to the examination tool, and configured to obtain a measurement related to the defect based on the image data, and estimate an actual depth of the defect in the specimen based on the measurement and the relationship.

2. The computerized system according to claim 1, wherein the specific EE is selected from the series of EEs as an EE that provides a relatively large separation between the expected measurements for the different expected depths of the defect.

3. The computerized system according to claim 1, wherein the relationship is derived by performing simulation of the expected measurements at the series of EEs based on material and structural properties of the semiconductor specimen.

4. The computerized system according to claim 1, wherein the relationship is derived by configuring the examination tool with multiple detectors, each configured for collecting BSEs at a respective EE of the series of EEs, scanning a set of test specimens having the defect located at different depths by the examination tool using the given LE, and obtaining the expected measurements at the series of EEs based on the BSEs respectively collected by the multiple detectors.

5. The computerized system according to claim 1, wherein the examination tool is configured with a band pass filter operatively connected to a BSE detector, wherein the band pass filter is configured to filter out BSEs emitted with one or more EEs other than the specific EE, thereby enabling the BSE detector to collect BSEs emitted only at the specific EE.

6. The computerized system according to claim 1, wherein the given LE used to scan the specimen is selected by deriving a set of relationships corresponding to a set of LEs, and selecting a LE of which the specific EE selected therefor provides the best separation between the expected measurements for the different expected depths of the defect.

7. The computerized system according to claim 1, wherein the semiconductor specimen comprises multiple layers and the defect is expected to be located at a set of candidate layers of the multiple layers.

8. The computerized system according to claim 7, wherein the semiconductor specimen is a Gate-all-around (GAA) transistor, and the defect is a residue expected to be located at a plurality of etching layers.

9. The computerized system according to claim 1, wherein the semiconductor specimen consists of a single layer and the defect is expected to be located at different depth levels in the single layer.

10. The computerized system according to claim 1, wherein the estimation of the actual depth of the defect based on the measurement and the relationship has improved throughput and accuracy with respect to estimation based on measurements obtained by scanning the specimen multiple times using multiple LEs.

11. A computerized method of examining a defect buried in a semiconductor specimen, the method comprising:
scanning, by an examination tool, the semiconductor specimen using an electron beam with a given landing energy (LE), and generating image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and
obtaining, by a processing circuitry operatively connected to the examination tool, a measurement related to the defect based on the image data, and estimating an actual depth of the defect in the specimen based on the measurement and the relationship.

12. The computerized method according to claim 11, wherein the specific EE is selected from the series of EEs as an EE that provides a relatively large separation between the expected measurements for the different expected depths of the defect.

13. The computerized method according to claim 11, wherein the relationship is derived by performing simulation of the expected measurements at the series of EEs based on material and structural properties of the semiconductor specimen.

14. The computerized method according to claim 11, wherein the relationship is derived by configuring the examination tool with multiple detectors each configured for collecting BSEs at a respective EE of the series of EEs, scanning a set of test specimens having the defect located at different depths by the examination tool using the given LE, and obtaining the expected measurements at the series of EEs based on the BSEs respectively collected by the multiple detectors.

15. The computerized method according to claim 1, wherein the BSEs emitted at the specific EE are collected by configuring the examination tool with a band pass filter operatively connected to a BSE detector, and using the band pass filter to filter out BSEs emitted with one or more EEs other than the specific EE, thereby enabling the BSE detector to collect BSEs emitted only at the specific EE.

16. The computerized method according to claim 11, wherein the given LE used to scan the specimen is selected by deriving a set of relationships corresponding to a set of LEs, and selecting a LE of which the specific EE selected therefor provides the best separation between the expected measurements for the different expected depths of the defect.

17. The computerized method according to claim 11, wherein the semiconductor specimen comprises multiple layers and the defect is expected to be located at a set of candidate layers of the multiple layers.

18. The computerized method according to claim 17, wherein the semiconductor specimen is a Gate-all-around (GAA) transistor, and the defect is a residue expected to be located at a plurality of etching layers.

19. The computerized method according to claim 11, wherein the specimen consists of a single layer and the defect is expected to be located at different depth levels in the single layer.

20. A non-transitory computer readable storage medium tangibly embodying a program of instructions that, when executed by a computer, cause the computer to perform a method of examining a defect buried in a semiconductor specimen, the method comprising:
causing an examination tool to scan the semiconductor specimen using an electron beam with a given landing energy (LE), and generating image data by collecting backscattered electrons (BSEs) emitted from the specimen at a specific escape energy (EE), wherein the specific EE is selected from a series of EEs corresponding to the given LE based on a relationship representative of expected measurements obtained at the series of EEs for different expected depths of the defect in the specimen; and
obtaining a measurement related to the defect based on the image data, and estimating an actual depth of the defect in the specimen based on the measurement and the relationship.
